(19) United States
(12) Patent Application Publication
(10) Pub. No.: US 2025/0072129 A1
(43) Pub. Date: Feb. 27, 2025

(54) MONOLITHIC OPTO-MOSFET RELAY AND MANUFACTURING METHOD THEREOF

(71) Applicant: Taiwan-Asia Semiconductor Corporation, Hsinchu City (TW)

(72) Inventor: Di-Bao WANG, Hsinchu City (TW)

(21) Appl. No.: 18/480,750

(22) Filed: Oct. 4, 2023

(30) Foreign Application Priority Data
Aug. 21, 2023 (TW) 112131309

(51) Int. Cl. H01L 31/112; H01L 29/16; H01L 29/51; H01L 29/66; H01L 31/101

(52) U.S. Cl. CPC H01L 31/1126; H01L 29/1608; H01L 29/517; H01L 29/6606; H01L 29/66068; H01L 31/1013

(57) ABSTRACT

A monolithic Opto-MOSFET relay and manufacturing method thereof are provided. The manufacturing method of the monolithic Opto-MOSFET relay involves using a low ion doping concentration substrate. In this method, a first P-N junction structure, a second P-N junction structure, and an N-P-N junction structure are formed within an epitaxial layer. Dry etching is employed to divide the epitaxial layer into a high-voltage region and a low-voltage region, which are electrically isolated from the each other. Subsequently, an isolation layer is deposited on the epitaxial layer, and photomask etching is performed to generate multiple patterns. A metal layer is then deposited to form a light emitting diode (LED) based on the pattern within the first P-N junction structure, a photodiode within the second P-N junction structure, and at least one MOSFET within the N-P-N junction structure.

### CROSS REFERENCE TO RELATED APPLICATION

This application claims the benefit of Taiwan Patent Application Serial No. 112131309 filed on Aug. 21, 2023, which is hereby incorporated by reference in its entirety.

### BACKGROUND OF THE INVENTION

### 1. Field of the Invention

The present invention relates to a monolithic Opto-MOSFET relay and manufacturing method thereof. Specifically, the present invention uses identical semiconductor process to manufacture the elements of the monolithic Opto-MOSFET relay on the same low ion doping concentration silicon carbide (SiC) substrate.

### 2. Description of Related Art

Currently, most manufacturing processes for opto-MOS relays use silicon substrates. The light emitting end, which is the light emitting diode (LED), is produced using gallium arsenide (GaAs) processes. In contrast, the light receiving end, including the photodiode (PD) and the metal-oxide-semiconductor field effect transistor (MOSFET), is produced using silicon, serving as optical sensors and AC switches. Consequently, there is a need of two separate chips with two different semiconductor processes for manufacturing the PD and the MOSFET, and thus results in complex packaging and lower efficiency.

Furthermore, the withstand voltage capacity of traditional silicon optical gates at the output end is limited. Without additional silicon carbide components, the traditional silicon optical gates can withstand approximately the off-state voltage from 800 volts to 900 volts at most.

In view of above issues, the present invention provides an integrated silicon carbide Opto-MOSFET relay to enhance withstand voltage capabilities and simplify the manufacturing process.

### SUMMARY OF THE INVENTION

An objective of the present disclosure is to provide a monolithic Opto-MOSFET relay and manufacturing method thereof. The monolithic Opto-MOSFET relay is manufactured by using a low ion doping concentration silicon carbide (SiC) substrate, and a light emitting element (i.e., light emitting diode) and a light receiving element (i.e., photodiode) that are needed to form the monolithic Opto-MOSFET relay are manufactured on the same SiC substrate to simplified manufacturing processes. Therefore, the withstand off-state voltage can be highly raised to 1700 volts without extra element, and thus reducing chip area and BOM cost.

To achieve the aforesaid objective, the present invention discloses a monolithic optoelectronic metal oxide semiconductor field effect transistor (Opto-MOSFET) relay which is connected to an input circuit and an output circuit, and includes a substrate, an epitaxial layer, an isolation layer, a light emitting diode (LED), a blue to ultraviolet light reflective film, a photodiode (PD), a first MOSFET, and a second MOSFET. The epitaxial layer is formed on the substrate. A groove is formed on the epitaxial layer to divide the epitaxial layer into a high voltage region and a low voltage region. The high voltage region and the low voltage region are electrically isolated from each other. The isolation layer is formed on the epitaxial layer. The LED is formed on the low voltage region of the epitaxial layer, and is configured to receive an input signal from the input circuit and generate an emission light in response to the input signal. The blue to ultraviolet light reflective film is configured to reflect the emission light and generate a reflection light. The PD is formed on the high voltage region of the epitaxial layer, and is configured to generate a sensing voltage in response to sensing the reflection light. The first MOSFET is formed on the high voltage region of the epitaxial layer and is electrically connected to the photodiode, and is configured to generate a first output current to the output circuit after being driven by the sensing voltage. The second MOSFET is formed on the high voltage region of the epitaxial layer and electrically connected to the photodiode, and is configured to generate a second output current to the output circuit after being driven by the sensing voltage. The LED, the PD, the first MOSFET and the second MOSFET are formed on the substrate.

In one embodiment, the substrate is made of silicon carbide (SiC) and is low ion doping concentration.

In one embodiment, the monolithic Opto-MOSFET relay is encapsulated by a molding compound after the blue to ultraviolet light reflective film is coated on the isolation layer. The blue to ultraviolet light reflective film reflects the emission light to the photodiode after the emission light is conducted to the blue to ultraviolet light reflective film through the isolation layer.

In one embodiment, the blue to ultraviolet light reflective film is coated on an outer face of a molding compound after the monolithic Opto-MOSFET relay is encapsulated by the molding compound. The blue to ultraviolet light reflective film reflects the emission light to the photodiode after the emission light is conducted to the blue to ultraviolet light reflective film through the molding compound.

In one embodiment, the blue to ultraviolet light reflective film is coated on an inner face of a metal case after the monolithic Opto-MOSFET relay is encapsulated by the metal case. The blue to ultraviolet light reflective film reflects the emission light to the photodiode after the emission light is conducted to the blue to ultraviolet light reflective film through an air inside the metal case.

In one embodiment, the epitaxial layer is N type doping.

In one embodiment, a wavelength of the emission light ranges from) 300 nanometers (nm) to 500 nm.

In one embodiment, the monolithic Opto-MOSFET relay includes a control circuit electrically connected to the PD, a first gate of the first MOSFET and a second gate of the second MOSFET, being configured to control a first voltage response time of the first MOSFET and a second voltage response time of the second MOSFET.

The present invention further discloses a monolithic opto metal oxide semiconductor field effect transistor (MOSFET) relay manufacturing method which includes growing an epitaxial layer on a substrate; implanting a plurality of ions to the epitaxial layer to form a first P-N structure, a second P-N structure and a N-P-N structure on the epitaxial layer; performing a dry etching to form a groove on the epitaxial layer, wherein the groove divides the epitaxial layer into a high voltage region and a low voltage region, the high voltage region and the low voltage region are electrically isolated from each other; depositing an isolation layer on the epitaxial layer and the groove; performing a photolithograph process to generate a plurality of patterns; and depositing a metal layer to form a light emitting diode (LED) at the first P-N structure, form a photodiode (PD) at the second P-N structure, and form a first MOSFET and a second MOSFET at the N-P-N structure based on the patterns.

In one embodiment, the monolithic Opto-MOSFET relay manufacturing method further includes coating a blue to ultraviolet light reflective film on the isolation layer; and encapsulating the monolithic Opto-MOSFET relay by a molding compound.

In one embodiment, the blue to ultraviolet light reflective film reflects an emission light to the photodiode after the emission light is conducted to the blue to ultraviolet light reflective film through the isolation layer.

In one embodiment, the monolithic Opto-MOSFET relay manufacturing method further includes encapsulating the monolithic Opto-MOSFET relay by a molding compound; and coating a blue to ultraviolet light reflective film on an outer face of the molding compound.

In one embodiment, the blue to ultraviolet light reflective film reflects an emission light to the photodiode after the emission light is conducted to the blue to ultraviolet light reflective film through the molding compound.

In one embodiment, the monolithic Opto-MOSFET relay manufacturing method further includes encapsulating the monolithic Opto-MOSFET relay by a metal case and coating a blue to ultraviolet light reflective film on an inner face of the metal case.

In one embodiment, the blue to ultraviolet light reflective film reflects an emission light to the photodiode after the emission light is conducted to the blue to ultraviolet light reflective film through an air inside the metal case.

In one embodiment, the substrate is made of silicon carbide (SiC) and is low ion doping concentration.

In one embodiment, the monolithic Opto-MOSFET relay manufacturing method further includes electrically connecting a control circuit to the PD, a first gate of the first MOSFET and a second gate of the second MOSFET; and controlling a first voltage response time of the first MOSFET and a second voltage response time of the second MOSFET when the PD generates a sensing voltage.

The detailed technology and preferred embodiments implanted for the present invention are described in the following paragraphs accompanying the appended drawings for people skilled in this field to well appreciate the features of the claimed invention.

### BRIEF DESCRIPTION OF THE DRAWINGS

FIG. 1 is a schematic view of manufacturing process of the monolithic Opto-MOSFET relay according to the present invention;

FIG. 2 is a cross sectional view of manufacturing process of the monolithic Opto-MOSFET relay according to the present invention;

FIG. 3 is a cross sectional view of manufacturing process of the monolithic Opto-MOSFET relay according to the present invention;

FIG. 4 is a cross sectional view of manufacturing process of the monolithic Opto-MOSFET relay according to the present invention;

FIG. 5 is a cross sectional view of manufacturing process of the monolithic Opto-MOSFET relay according to the present invention;

FIG. 6 is a cross sectional view of manufacturing process of the monolithic Opto-MOSFET relay according to the present invention;

FIG. 7 is a cross sectional view of manufacturing process of the monolithic Opto-MOSFET relay according to the present invention;

FIG. 8 is a top view of the monolithic Opto-MOSFET relay according to the present invention;

FIG. 9 is a cross sectional view of packaged monolithic Opto-MOSFET relay according to the present invention;

FIG. 10 is a cross sectional view of packaged monolithic Opto-MOSFET relay according to the present invention;

FIG. 11 is a cross sectional view of packaged monolithic Opto-MOSFET relay according to the present invention;

FIG. 12 is a control circuit for monolithic Opto-MOSFET relay according to the present invention; and

FIG. 13 is a flow chart of manufacturing the monolithic Opto-MOSFET relay according to the present invention.

### DETAILED DESCRIPTION OF THE PREFERRED EMBODIMENT

Reference will now be made in detail to the present embodiments of the invention, examples of which are illustrated in the accompanying drawings, and are not intended to limit the present invention, applications or particular implementations described in these embodiments. Wherever possible, the same reference numbers are used in the drawings and the description to refer to the same or like parts. It shall be appreciated that, in the following embodiments and the attached drawings, elements unrelated to the present invention are omitted from depiction; and dimensional relationships among individual elements in the attached drawings are provided only for ease of understanding, but not to limit the actual scale.

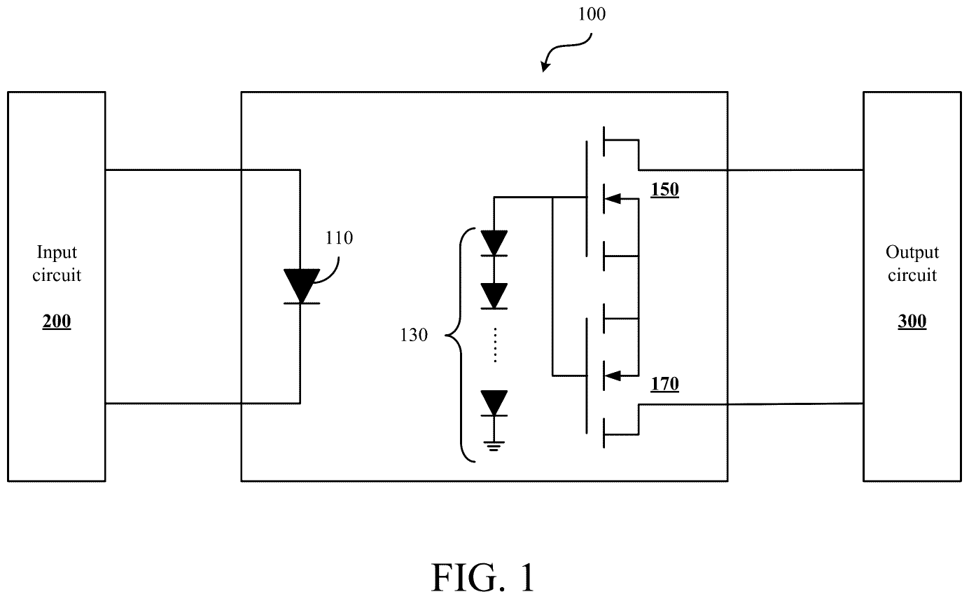

A first embodiment of the present invention is as shown in FIG. 1 to FIG. 8. FIG. 1 depicts a schematic circuit view of the monolithic Opto-MOSFET relay 100 of the present invention. The monolithic Opto-MOSFET relay 100 is connected to an input circuit 200 and an output circuit 300. The monolithic Opto-MOSFET relay 100 includes a light emitting diode (LED) 110, a photodiode (PD) 130, a first metal oxide semiconductor field effect transistor (MOSFET) 150, and a second MOSFET 170. The first MOSFET 150 includes a first gate 151, a first source 153, and a first drain 155. The second MOSFET 170 includes a second gate 171, a second source 173, and a second drain 175.

The light emitting diode 110 receives an input signal from the input circuit 200 and generates an emission light 111 in response to the input signal. The emission light 111 is reflected to form a reflected light 113. The photodiode 130 generates a responsive current and consequently creates a voltage difference across its terminals when detecting the reflected light 113. The voltage difference is used to control the first gate 151 of the first MOSFET 150 and the second gate 171 of the second MOSFET 170.

Compared to the existing technology where photo-relays require manufacturing a light emitting diode on one chip and manufacturing a photodiode along with MOSFETs on another chip, the present technology offers a significant improvement. In other words, existing technology needs at least two separate chips to manufacture a photo-relay. Because the chip for manufacturing the LED is different from the chip for manufacturing the photodiode and MOSFETs, the manufacturing processes for these components are also different. Furthermore, conventional photo-relays manufactured on silicon substrates have limited voltage tolerance at the output end. Without additional silicon carbide (SiC) components, the maximum withstand voltage of conventional photo-relays are only 800 volts to 900 volts.

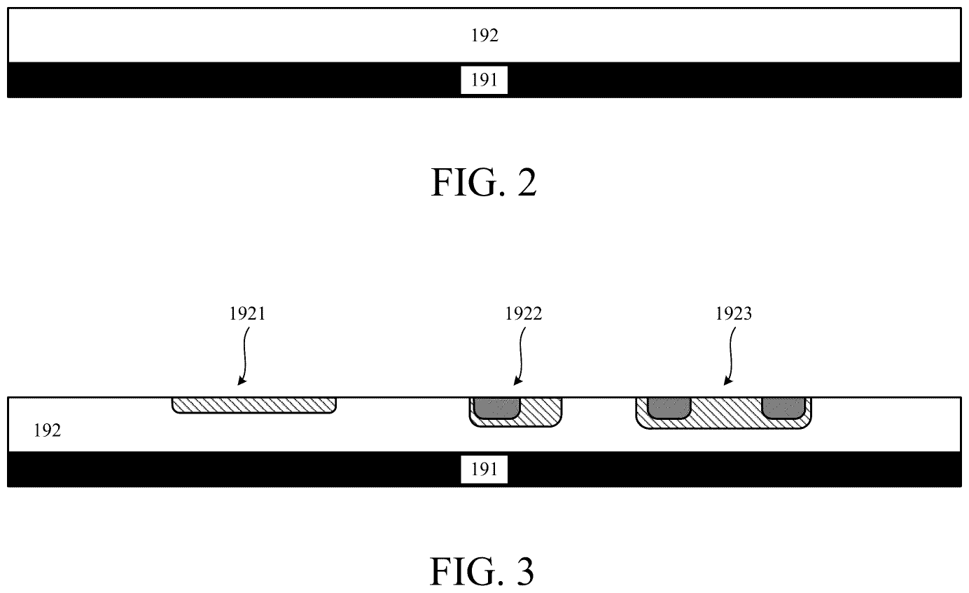

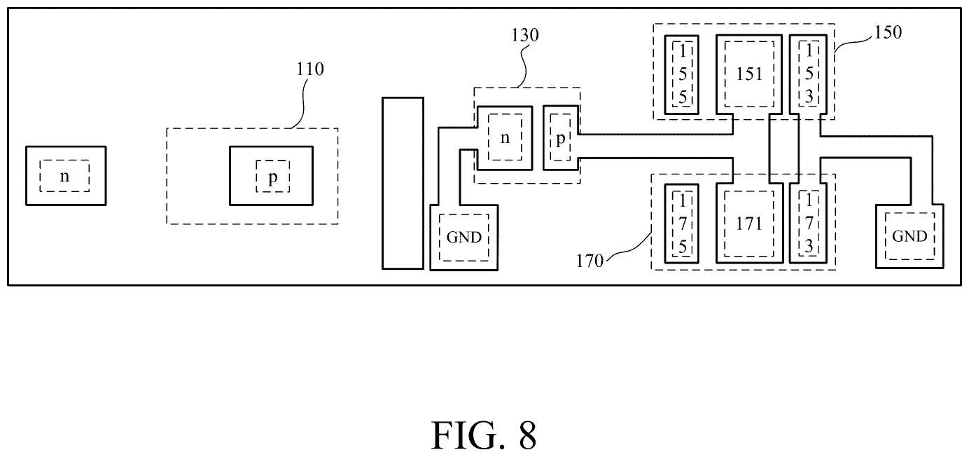

To simplify the manufacturing process, reduce overall costs, and enhance the off-state voltage tolerance, the present invention proposes manufacturing of the required light emitting element (i.e., light emitting diode) and light receiving element (i.e., photodiode) for the photo-relay on the same SiC substrate to simplify the manufacturing process. To be more specific, please refer to FIGS. 2 to 8, where FIGS. 2 to 7 show cross-sectional views of the monolithic Opto-MOSFET relay 100 at different stages of the manufacturing process. FIG. 8 shows a top view of the circuit layout of the monolithic Opto-MOSFET relay 100. In the manufacturing process of the monolithic opto-MOSFET relay 100 of the present invention, an epitaxial layer 192 is first grown on a substrate 191. A plurality of ions are then implanted into the epitaxial layer 192 to form a first P-N structure 1921, a second P-N structure 1922, and an N-P-N structure 1923 within the epitaxial layer 192, as shown in FIGS. 2 and 3.

The substrate 191 is manufactured using SiC with a low ion doping concentration, generally less than 1E15 (1/cm³). SiC exists in different crystalline structures, including hexagonal silicon carbide (6H-SiC), tetragonal silicon carbide (4H-SiC), and cubic silicon carbide (3C-SiC). SiC offers high temperature stability, high electron mobility, excellent voltage tolerance, and exceptional thermal conductivity. Therefore, compared to photo-relays manufactured with silicon substrates in existing technologies, using SiC in the manufacturing of the monolithic Opto-MOSFET relay 100 in the present invention significantly enhances its AC withstand voltage.

In this embodiment, the epitaxial layer 192 is N-type doping. Ions may involve either N-type ions or P-type ions. In detail, reference is made to FIG. 3, the hatched region represents the P-type doping region in FIG. 3, and the gray region represents the N-type doping region. Through ion implantation, the first P-N structure 1921 is formed by implanting P-type ions into the N-type epitaxial layer, creating a P-N junction in the P-type doping region and the N-type epitaxial layer. Similarly, the second P-N structure 1922 is formed by implanting P-type ions into the N-type epitaxial layer to create the P-type doping region, and then forming a P-N junction within the P-type doping region through implanting N-type ions. Following a similar process to that of the second P-N structure 1922, the N-P-N structure 1923 is formed by implanting P-type ions into the N-type epitaxial layer to create the P-type doping region, and then implanting N-type ions into two different regions within the P-type doping region to create the N-P-N structure 1923.

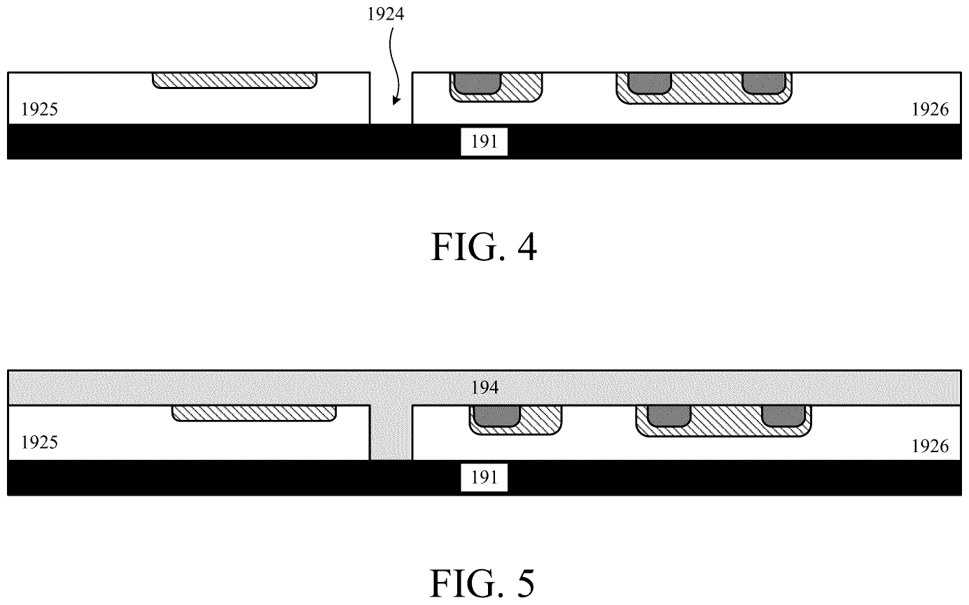

Next, reference is made to FIG. 4, where a dry etching process is performed to create a groove 1924 in the epitaxial layer 192. Dry etching is a process that selectively removes material from the surface of a wafer using plasma. The groove 1924 divides the epitaxial layer 192 into a low voltage region 1925 and a high voltage region 1926. To achieve electrical isolation between the low voltage region 1925 and the high voltage region 1926, the depth of the dry etching needs to reach the level of the substrate 191, and exposing the surface of the substrate 191. In this situation, the low voltage region 1925 and the high voltage region 1926 are only connected via the substrate 191. Since the substrate 191 is low ion doping concentration, it has a high electrical resistance. In other words, the substrate 191 prevents any electrical changes between the low voltage region 1925 and the high voltage region 1926, ensuring complete electrical isolation.

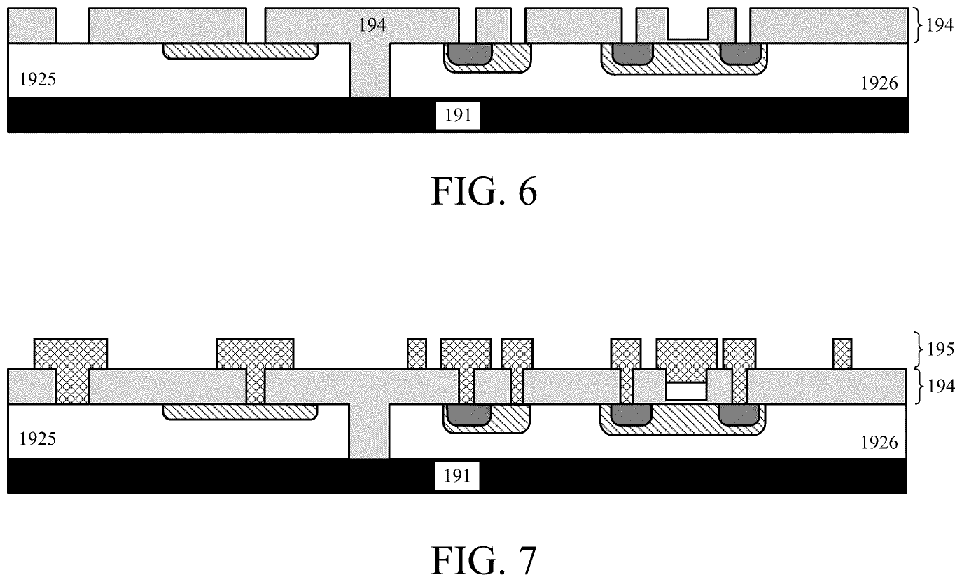

After completing the dry etching process, an isolation layer 194 is deposited on both the epitaxial layer 192 and the groove 1924. Subsequently, a photolithography process is carried out to generate various patterns (not shown in the figures), and a metal layer 195 is deposited. Based on these patterns, the light emitting diode LED 110 is formed at the first P-N structure 1921, the photodiode 130 is formed at the second P-N structure 1922, and the first MOSFET 150 and the second MOSFET 170 are formed at the N-P-N structure 1923, as shown in FIGS. 5 and 6.

In this embodiment, the isolation layer 194 is manufactured by using deposition methods such as chemical vapor deposition (CVD), physical vapor deposition (PVD), or sputtering during the manufacturing process. The materials used for manufacturing the isolation layer 194 may include silicon dioxide (SiO₂) or silicon nitride (Si₃N₄). Both silicon dioxide and silicon nitride are insulating materials used primarily to prevent the flow of current between different regions, such as between the low voltage region 1925 and the high voltage region 1926.

The patterns generated through photolithography are positioned to correspond to the first P-N structure 1921, the second P-N structure 1922, and the N-P-N structure 1923, as shown in FIG. 6. Therefore, after the deposition of the metal layer 195, a light emitting diode 110 is formed in the first P-N structure 1921, a photodiode 130 is formed in the second P-N structure 1922, and a first metal oxide semiconductor field-effect transistor (MOSFET) 150 and a second MOSFET 170 are formed in the N-P-N structure 1923, as shown in FIGS. 7 and 8.

The light emitting diode 110 is formed at the low voltage region 1925 of the epitaxial layer 192. The light emitting diode 110 may receive an input signal from the input circuit and generate the emission light 111 in response to the input signal. The photodiode 130 is formed at the high voltage region 1926 of the epitaxial layer 192. The photodiode 130 may sense the reflected light 113 and generate a sensing voltage. The first MOSFET 150 is formed at the high voltage region 1926 of the epitaxial layer 192 and is electrically connected to the photodiode 130. The first MOSFET 150 may generate a first output current and transmit the first output current to the output circuit 300 after being driven by the sensing voltage. The second MOSFET 170 is formed at the high voltage region 1926 of the epitaxial layer 192 and is electrically connected to the photodiode 130. The second MOSFET 170 may generate a second output current and transmit the second output current to the output circuit after being driven by the sensing voltage.

As a result, the light emitting diode 110, the photodiode 130, the first MOSFET 150, and the second MOSFET 170 are manufactured using the same process on the same substrate 191, and are formed adjacent to each other on the substrate 191. Therefore, in the present invention, it is possible to significantly increase the AC withstand voltage to above 1700 volts (V) without additional components. This not only reduces chip area but also reduce Bill of Materials (BOM) cost.

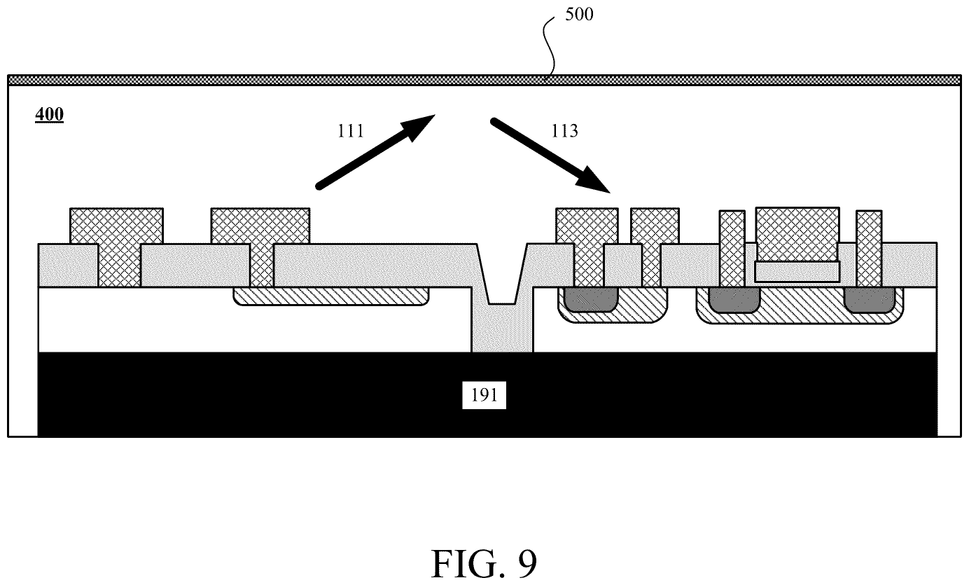

A second embodiment of the present invention is as shown in FIG. 9, which depicts a cross-sectional view of the monolithic Opto-MOSFET relay 100. The second embodiment is an extension of the first embodiment. This embodiment will further describe the packaging of the monolithic Opto-MOSFET relay 100. Specifically, the monolithic Opto-MOSFET relay 100 is encapsulated with transparent molding compounds 400, and a blue to ultraviolet light reflective film 500 is coated on an outer surface of the molding compound 400. The blue to ultraviolet light reflective film 500 may reflect the emission light 111 to create reflected light 113. Therefore, the emission light 111 from the light emitting diode 110 is conducted to the blue to ultraviolet light reflective film 500 through the molding compound 400, and the blue to ultraviolet light reflective film 500 reflects the emission light 111 to the photodiode 130. The emission light 111 emitted by the light emitting diode 110 is blue light to ultraviolet light, with a wavelength ranging from 300 nanometers to 500 nanometers.

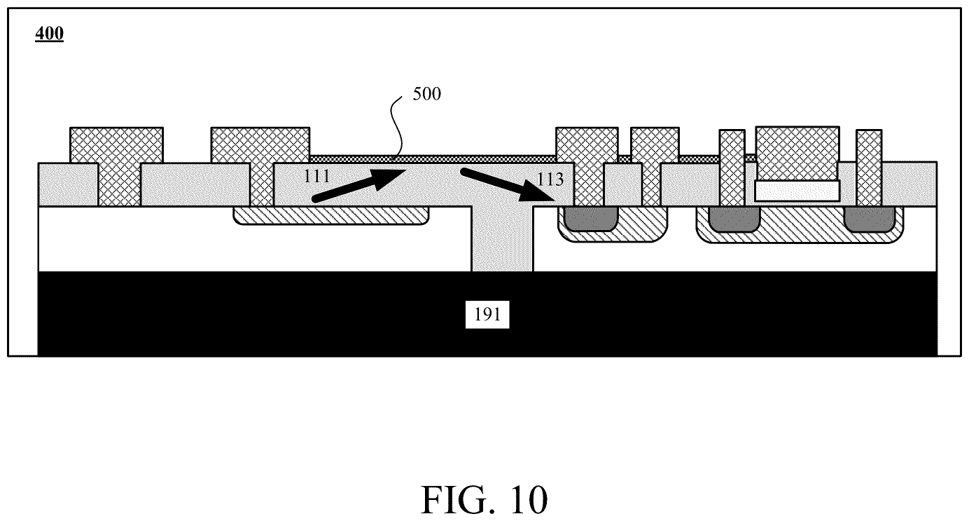

A third embodiment of the present invention is as shown in FIG. 10, which depicts a cross-sectional view of an alternative configuration of the monolithic Opto-MOSFET relay 100. The third embodiment is an extension of the first embodiment. Different from the second embodiment, in this embodiment, the blue to ultraviolet light reflective film 500 is first coated on the isolation layer 194 before encapsulating the monolithic Opto-MOSFET relay 100 with the molding compound 400. Therefore, the emission light 111 emitted by the light emitting diode 110 is conducted to the blue to ultraviolet light reflective film 500 through the isolation layer 194, and is reflected to the photodiode 130 by the blue to ultraviolet light reflective film 500.

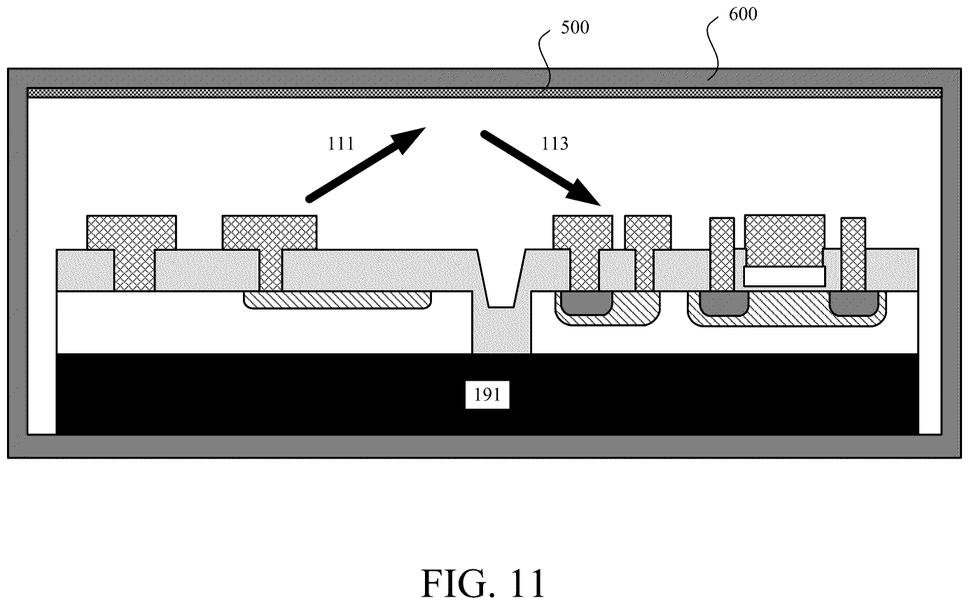

A fourth embodiment of the present invention is as shown in FIG. 11 which depicts a cross-sectional view of an alternative configuration of the monolithic Opto-MOSFET relay 100. The fourth embodiment is an extension of the first embodiment. Different from the second embodiment and the third embodiment, in this embodiment, the monolithic Opto-MOSFET relay 100 is first encapsulated by a metal case 600. Subsequently, the blue to ultraviolet light reflective film 500 is coated on an inner surface of the metal case 600, and no molding compound is filled inside the metal case 600. Therefore, the emission light 111 emitted by the light emitting diode 110 is conducted through the air inside the metal case 600 to the blue to ultraviolet light reflective film 500, and is reflected to the photodiode 130 by the blue to ultraviolet light reflective film 500.

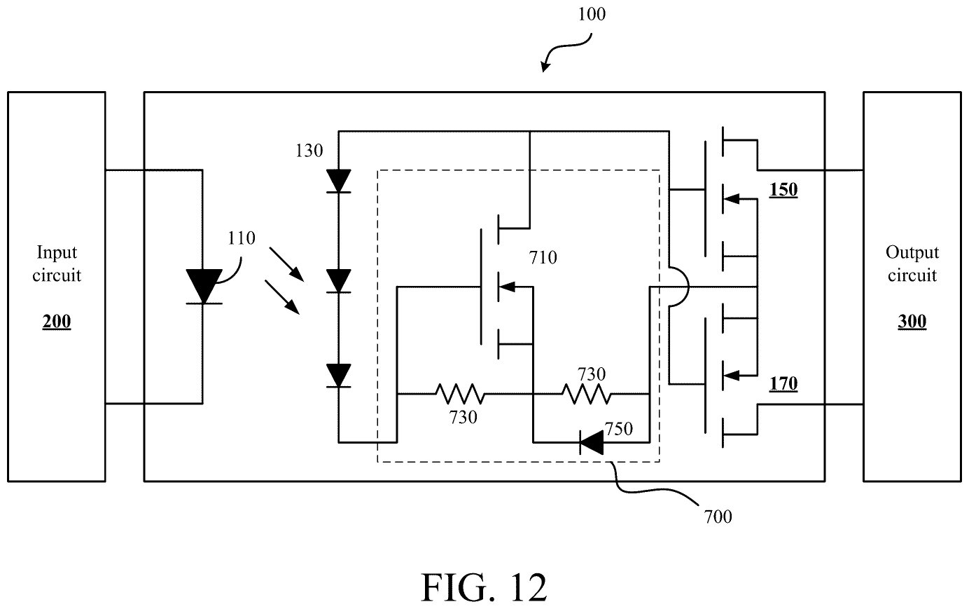

A fifth embodiment of the present invention is as shown in FIG. 12 which depicts a schematic view of a control circuit 700 used in the monolithic Opto-MOSFET relay of the present invention. The fifth embodiment is an extension of the first embodiment. The control circuit 700 includes at least one MOSFET 710, at least one resistor 730, and at least one diode 750, as schematically shown in FIG. 12. The control circuit 700 is electrically connected to the photodiode 130, the first gate 151 of the first MOSFET 150, and the second gate 171 of the second MOSFET 170. The control circuit 700 may control the first voltage response time of the first MOSFET 150 and the second voltage response time of the MOSFET 170. In addition, during the manufacturing process, the control circuit 700, along with the light emitting diode 110, the photodiode 130, the first MOSFET 150, and second MOSFET 170, are manufactured under the same manufacturing process on the same SiC substrate 191.

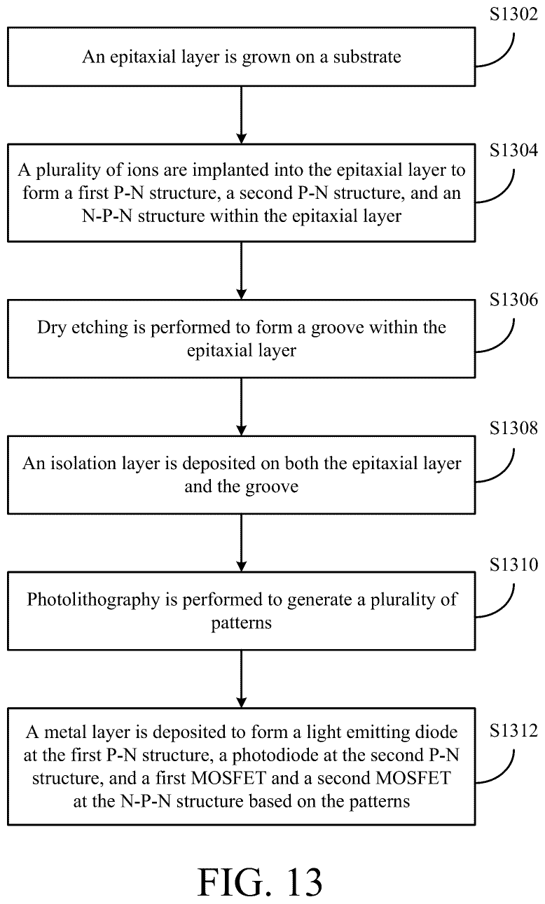

A sixth embodiment of the present invention is as shown in FIG. 13 which is a flowchart of the monolithic Opto-MOSFET relay manufacturing method of the present invention. This manufacturing method is applicable to manufacture the monolithic Opto-MOSFET relay 100 described in above embodiments. The monolithic Opto-MOSFET relay manufacturing method involves various semiconductor equipment, including deposition equipment, ion implantation machines, photolithography tools, etching equipment, cleaning equipment, sputtering machines, testing equipment, and packaging equipment, but not limited thereto.

First, in step S1302, an epitaxial layer is grown on a substrate, as illustrated, for example, in FIGS. 2 to 7. The substrate is made of SiC and is low ion doping concentration. In step S1304, a plurality of ions are implanted into the epitaxial layer to form a first P-N structure, a second P-N structure, and an N-P-N structure within the epitaxial layer. In step S1306, dry etching is performed to form a groove within the epitaxial layer. The groove divides the epitaxial layer into a high voltage region and a low voltage region, ensuring electrical isolation between the high voltage region and the low voltage region.

Then, in step S1308, an isolation layer is deposited on both the epitaxial layer and the groove. In step S1310, photolithography is performed to generate a plurality of patterns. In step S1312, a metal layer is deposited to form a light emitting diode at the first P-N structure, a photodiode at the second P-N structure, and a first MOSFET and a second MOSFET at the N-P-N structure based on the patterns.

In one embodiment, the monolithic Opto-MOSFET relay is encapsulated by a molding compound, and a blue to ultraviolet light reflective film is coated on an outer surface of the molding compound. The emission light is conducted through the molding compound to the blue to ultraviolet light reflective film and is reflected by the blue to ultraviolet light reflective film to the photodiode, as described in the second embodiment and as shown in FIG. 9.

In other embodiments, the blue to ultraviolet light reflective film is coated on the isolation layer, and then the monolithic Opto-MOSFET relay is encapsulated by the molding compound. In this case, the emission light is conducted through the isolation layer to the blue to ultraviolet light reflective film and is reflected by the blue to ultraviolet light reflective film to the photodiode, as described in the third embodiment and as shown in FIG. 10.

In other embodiments, the monolithic Opto-MOSFET relay is encapsulated by a metal case, and then the blue to ultraviolet light reflective film is coated on an inner surface of the metal case. In this case, the emission light is conducted through the air inside the metal case to the blue to ultraviolet light reflective film and is reflected by the blue to ultraviolet light reflective film to the photodiode, as described in the fourth embodiment and shown in FIG. 11.

Furthermore, in other embodiments, the monolithic Opto-MOSFET relay manufacturing method of the present invention may further electrically connects a control circuit to the photodiode and to the first gate of the first MOSFET and the second gate of the second MOSFET. When the photodiode generates a sensing voltage, the control circuit controls the first voltage response time of the first MOSFET and the second voltage response time of the second MOSFET.

In addition to the aforesaid steps, the monolithic Opto-MOSFET relay manufacturing method of the present invention can also execute all the operations described in the aforesaid embodiments and have all the corresponding functions, and how this embodiment executes these operations and has these functions based on the aforesaid embodiments shall be readily appreciated by those of ordinary skill in the art, and thus will not be further described herein.

According to the above descriptions, the monolithic Opto-MOSFET relay of the present invention is manufactured on a low ion doping concentration silicon carbide substrate. Compared to silicon substrates used in existing technologies, silicon carbide has an electrical breakdown strength ten times that of silicon and can simultaneously be used to produce light emitting components and light-receiving components. Therefore, in the present invention, after growing an epitaxial layer and ion implantation on a silicon carbide substrate, the epitaxial layer is divided into two parts through dry etching. An isolation layer is deposited, followed by photolithographic etching, and finally, a metal layer is deposited. This process simultaneously forms a light-emitting diode, a photodiode, and a metal-oxide-semiconductor field-effect transistor (MOSFET) in the two parts of the epitaxial layer. Consequently, the present invention manufactures all the components of the monolithic Opto-MOSFET relay on the same substrate using a single process, eliminating the need for additional components, significantly increasing the AC voltage withstand capability, reducing chip size, and lowering module costs.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A monolithic optoelectronic metal oxide semiconductor field effect transistor (Opto-MOSFET) relay being connected to an input circuit and an output circuit, comprising:
a substrate;
an epitaxial layer formed on the substrate, a groove formed on the epitaxial layer to divide the epitaxial layer into a high voltage region and a low voltage region, the high voltage region and the low voltage region are electrically isolated from each other;
an isolation layer formed on the epitaxial layer;
a light emitting diode (LED) formed on the low voltage region of the epitaxial layer, being configured to receive an input signal from the input circuit and generate an emission light in response to the input signal;
a blue to ultraviolet light reflective film being configured to reflect the emission light and generate a reflection light;
a photodiode (PD) formed on the high voltage region of the epitaxial layer, being configured to generate a sensing voltage in response to sensing the reflection light;
a first MOSFET formed on the high voltage region of the epitaxial layer and electrically connected to the photodiode, being configured to generate a first output current to the output circuit after being driven by the sensing voltage; and
a second MOSFET formed on the high voltage region of the epitaxial layer and electrically connected to the photodiode, being configured to generate a second output current to the output circuit after being driven by the sensing voltage;
wherein the LED, the PD, the first MOSFET and the second MOSFET are formed on the substrate.

2. The monolithic Opto-MOSFET relay as claimed in claim 1, wherein the substrate is made of silicon carbide (SiC) and is low ion doping concentration.

3. The monolithic Opto-MOSFET relay as claimed in claim 1, wherein the monolithic Opto-MOSFET relay is encapsulated by a molding compound after the blue to ultraviolet light reflective film is coated on the isolation layer.

4. The monolithic Opto-MOSFET relay as claimed in claim 3, wherein the blue to ultraviolet light reflective film reflects the emission light to the photodiode after the emission light is conducted to the blue to ultraviolet light reflective film through the isolation layer.

5. The monolithic Opto-MOSFET relay as claimed in claim 1, wherein the blue to ultraviolet light reflective film is coated on an outer face of a molding compound after the monolithic Opto-MOSFET relay is encapsulated by the molding compound.

6. The monolithic Opto-MOSFET relay as claimed in claim 5, wherein the blue to ultraviolet light reflective film reflects the emission light to the photodiode after the emission light is conducted to the blue to ultraviolet light reflective film through the molding compound.

7. The monolithic Opto-MOSFET relay as claimed in claim 1, wherein the blue to ultraviolet light reflective film is coated on an inner face of a metal case after the monolithic Opto-MOSFET relay is encapsulated by the metal case.

8. The monolithic Opto-MOSFET relay as claimed in claim 7, wherein the blue to ultraviolet light reflective film reflects the emission light to the photodiode after the emission light is conducted to the blue to ultraviolet light reflective film through an air inside the metal case.

9. The monolithic Opto-MOSFET relay as claimed in claim 1, wherein the epitaxial layer is N type doping.

10. The monolithic Opto-MOSFET relay as claimed in claim 1, wherein a wavelength of the emission light ranges from 300 nanometers (nm) to 500 nm.

11. The monolithic Opto-MOSFET relay as claimed in claim 1, further comprising:
a control circuit electrically connected to the PD, a first gate of the first MOSFET and a second gate of the second MOSFET, being configured to control a first voltage response time of the first MOSFET and a second voltage response time of the second MOSFET.

12. A monolithic optoelectronic metal oxide semiconductor field effect transistor (Opto-MOSFET) relay manufacturing method, comprising:
growing an epitaxial layer on a substrate;
implanting a plurality of ions to the epitaxial layer to form a first P-N structure, a second P-N structure and a N-P-N structure on the epitaxial layer;
performing a dry etching to form a groove on the epitaxial layer, wherein the groove divides the epitaxial layer into a high voltage region and a low voltage region, the high voltage region and the low voltage region are electrically isolated from each other;
depositing an isolation layer on the epitaxial layer and the groove;
performing a photolithograph process to generate a plurality of patterns; and
depositing a metal layer to form a light emitting diode (LED) at the first P-N structure, form a photodiode (PD) at the second P-N structure, and form a first MOSFET and a second MOSFET at the N-P-N structure based on the patterns.

13. The monolithic Opto-MOSFET relay manufacturing method as claimed in claim 12, further comprising:
coating a blue to ultraviolet light reflective film on the isolation layer; and
encapsulating the monolithic Opto-MOSFET relay by a molding compound.

14. The monolithic Opto-MOSFET relay manufacturing method as claimed in claim 13, wherein the blue to ultraviolet light reflective film reflects an emission light to the photodiode after the emission light is conducted to the blue to ultraviolet light reflective film through the isolation layer.

15. The monolithic Opto-MOSFET relay manufacturing method as claimed in claim 12, further comprising:
encapsulating the monolithic Opto-MOSFET relay by a molding compound; and
coating a blue to ultraviolet light reflective film on an outer face of the molding compound.

16. The monolithic Opto-MOSFET relay manufacturing method as claimed in claim 15, wherein the blue to ultraviolet light reflective film reflects an emission light to the photodiode after the emission light is conducted to the blue to ultraviolet light reflective film through the molding compound.

17. The monolithic Opto-MOSFET relay manufacturing method as claimed in claim 12, further comprising:
encapsulating the monolithic Opto-MOSFET relay by a metal case and
coating a blue to ultraviolet light reflective film on an inner face of the metal case.

18. The monolithic Opto-MOSFET relay manufacturing method as claimed in claim 17, wherein the blue to ultraviolet light reflective film reflects an emission light to the photodiode after the emission light is conducted to the blue to ultraviolet light reflective film through an air inside the metal case.

19. The monolithic Opto-MOSFET relay manufacturing method as claimed in claim 12, wherein the substrate is made of silicon carbide (SiC) and is low ion doping concentration.

20. The monolithic Opto-MOSFET relay manufacturing method as claimed in claim 12, further comprising:
electrically connecting a control circuit to the PD, a first gate of the first MOSFET and a second gate of the second MOSFET; and
controlling a first voltage response time of the first MOSFET and a second voltage response time of the second MOSFET when the PD generates a sensing voltage.
